(19) United States
(12) Patent Application Publication
(10) Pub. No.: US 2015/0030117 A1
(43) Pub. Date: Jan. 29, 2015

(54) Shift frequency divider circuit

(71) Applicant: IPGoal Microelectronics (Sichuan) Co., Ltd., Chengdu (CN)

(72) Inventor: Guo Zhang, Chengdu (CN)

(73) Assignee: IPGoal Microelectronics (Sichuan) Co., Ltd.

(21) Appl. No.: 14/515,388

(22) Filed: Oct. 15, 2014

(30) Foreign Application Priority Data
Mar. 27, 2014 (CN) 201410120698.0

(51) Int. Cl. H03K 21/40; H03K 21/38

(52) U.S. Cl. CPC H03K 21/40; H03K 21/38
USPC 377/47

(57) ABSTRACT

A shift frequency divider circuit includes: an inverter; N−1 registers; and N−2 logic gates; wherein each reset terminal of the register is connected to a system reset signal terminal; an output terminal of the inverter is respectively connected to an input terminal of the No. 1 register and input terminals of all the logic gates; all the logic gates are respectively connected between output terminals and input terminals of the No. 1 register to the No. N−1 register, and the output terminal of the No. 1 register is connected to another input terminal of the No. 1 logic gate, an output terminal of the No. 1 logic gate is connected to the input terminal of the No. 2 register; an output terminal of the No. N−2 logic gate is connected to the input terminal of the No. N−1 register.

### CROSS REFERENCE OF RELATED APPLICATION

The present invention claims priority under 35 U.S.C. 119(a-d) to CN 201410120698.0, filed Mar. 27, 2014.

### BACKGROUND OF THE PRESENT INVENTION

1. Field of Invention

The present invention relates to a technical field of digital IC (integrated circuit), and more particularly to a shift frequency divider circuit.

2. Description of Related Arts

Generally, there are two kinds of frequency divider: shift frequency divider and counting frequency divider.

Compared with the shift frequency divider, the counting frequency divider has a more complex control logic of the phase, and sequence requirements in high-frequency design are not satisfied. Therefore, the counting frequency divider is usually utilized in the frequency divider for clock with medium or low frequency. The shift frequency divider has simple logic for satisfying sequence requirements even in high-frequency designs. Therefore, the shift frequency divider is usually utilized in the frequency divider for clock with high frequency. However, in the conventional shift frequency divider, clock quality after frequency division depends on an initial state of the register set and state transformation during operation. In case of state error due to unforeseen reasons, the frequency division problems or even total error would be caused.

Therefore, for solving the above problems, an improved shift frequency divider is provided.

### SUMMARY OF THE PRESENT INVENTION

An object of the present invention is to provide a shift frequency divider circuit which has a simple structure in such a manner that less registers and logic gates are needed to fulfill a same requirement of frequency divider, and is able to regain normal frequency divide ability after being disturbed.

Accordingly, in order to accomplish the above objects, the present invention provides a shift frequency divider circuit, which is a fractional-N shift frequency divider, wherein the N is a positive integer larger than or equal to 2; the shift frequency divider circuit comprises:

an inverter;

N−1 registers; and

N−2 logic gates;

wherein a reset terminal of each register is connected to a system reset signal terminal; a clock terminal of each register is connected to an external high frequency clock terminal; an output terminal of the No. N−1 register is connected to an input terminal of the inverter, an output terminal of the inverter is respectively connected to an input terminal of the No. 1 register and input terminals of all the logic gates; all the logic gates are respectively connected between output terminals and input terminals of the No. 1 register to the No. N−1 register, and the output terminal of the No. 1 register is connected to another input terminal of the No. 1 logic gate, an output terminal of the No. 1 logic gate is connected to the input terminal of the No. 2 register, the output terminal of the No. N−2 register is connected to another input terminal of the No. N−1 logic gate; and, an output terminal of the No. N−2 logic gate is connected to the input terminal of the No. N−1 register.

Preferable, the N equals to 2; the shift frequency divider circuit comprises:

an inverter; and

a register;

wherein an output terminal of the register is connected to an input terminal of the inverter; an output terminal of the inverter is connected to an input terminal of the register.

Preferably, the logic gate is an AND gate.

Preferably, the logic gate is an OR gate.

Compared with the conventional technology, the shift frequency divider circuit according to the present invention comprises N−2 the logic gates in such a manner that only N−1 the registers are needed for fractional-N frequency division. A structure of the shift frequency divider is simplified and is convenient to be realized. Furthermore, the inverter of the shift frequency divider circuit according to the present invention inverts an output result of the No. N−1 register in each clock cycle and inputs the output result into the No. 1 register as well as the logic gates, in such a manner that when an intermediate state of the shift frequency divider is wrong, the shift frequency divider will be recovered within a certain period with a same division ratio. With the foregoing structure, an application scope of the shift frequency divider circuit is widened and external distribution on the division is decreased.

These and other objectives, features, and advantages of the present invention will become apparent from the following detailed description, the accompanying drawings, and the appended claims.

### BRIEF DESCRIPTION OF THE DRAWINGS

FIG. 1 is a block diagram of a shift frequency divider circuit according the present invention.

FIG. 2 is a schematic view of a shift frequency divider circuit according to a first preferred embodiment of the present invention.

FIG. 3 is a schematic view of the shift frequency divider circuit as shown in the FIG. 2 when providing fractional-6 frequency division.

FIG. 4 is sequence chart of the shift frequency divider circuit as shown in the FIG. 3 in a normal state.

FIG. 5 is sequence chart of the shift frequency divider circuit as shown in the FIG. 3 when disturbed.

FIG. 6 is a schematic view of the shift frequency divider circuit according to a second preferred embodiment of the present invention.

FIG. 7 is a schematic view of the shift frequency divider circuit as shown in the FIG. 6 for providing fractional-6 frequency division.

FIG. 8 is sequence chart of the shift frequency divider circuit as shown in the FIG. 7 in a normal state.

FIG. 9 is sequence chart of the shift frequency divider circuit as shown in the FIG. 7 when disturbed.

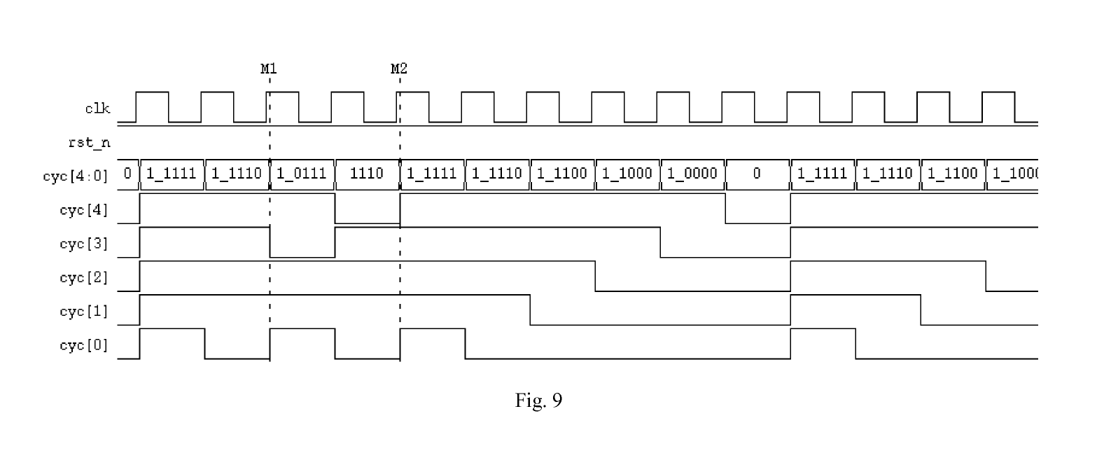

FIG. 10 is a schematic view of the shift frequency divider circuit according to a third preferred embodiment of the present invention.

### DETAILED DESCRIPTION OF THE PREFERRED EMBODIMENT

Referring to the drawings, the same reference numbers refer to the same elements. As mentioned above, a shift frequency divider circuit which has a simple structure is provided, in such a manner that less registers and logic devices are needed with a same requirement of frequency divider, and the shift frequency divider is able to regain normal frequency divide ability after being disturbed.

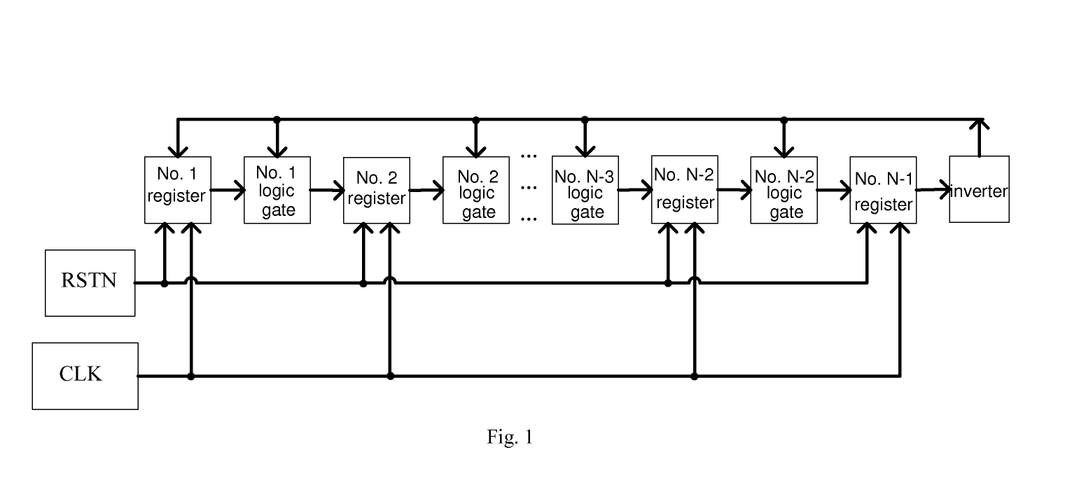

Referring to FIG. 1 of the drawings, the present invention provides a shift frequency divider circuit, which is a fractional-N shift frequency divider, wherein the N is a positive integer larger than or equal to 2; the shift frequency divider circuit comprises:

an inverter;

N−1 registers; and

N−2 logic gates;

wherein a reset terminal of each register is connected to a system reset signal terminal; each clock terminal of the register is connected to an external high frequency clock terminal; an output terminal of the No. N−1 register is connected to an input terminal of the inverter, an output terminal of the inverter is respectively connected to an input terminal of the No. 1 register and input terminals of all the logic gates; all the logic gates are respectively connected between output terminals and input terminals of the No. 1 register to the No. N−1 register, and the output terminal of the No. 1 register is connected to another input terminal of the No. 1 logic gate, an output terminal of the No. 1 logic gate is connected to the input terminal of the No. 2 register; an output terminal of the No. N−2 logic gate is connected to the input terminal of the No. N−1 register. Therefore, an output result of the No. N−1 register is inverted and directly inputted into the No. 1 register, and input signals of the No. 2 register to the No. N−1 register are all logical operation results by the logic gates of an output result of the previous register and the output result of the No. N−1 register after being inverted. As a result, after N clock pulses, the No. N−1 register is always able to completely reset the other N−2 registers to the initial state. Thereafter, a cycle of the N states is provided again in such a manner that even if disturbance happens, the shift frequency divider circuit is able to be recovered.

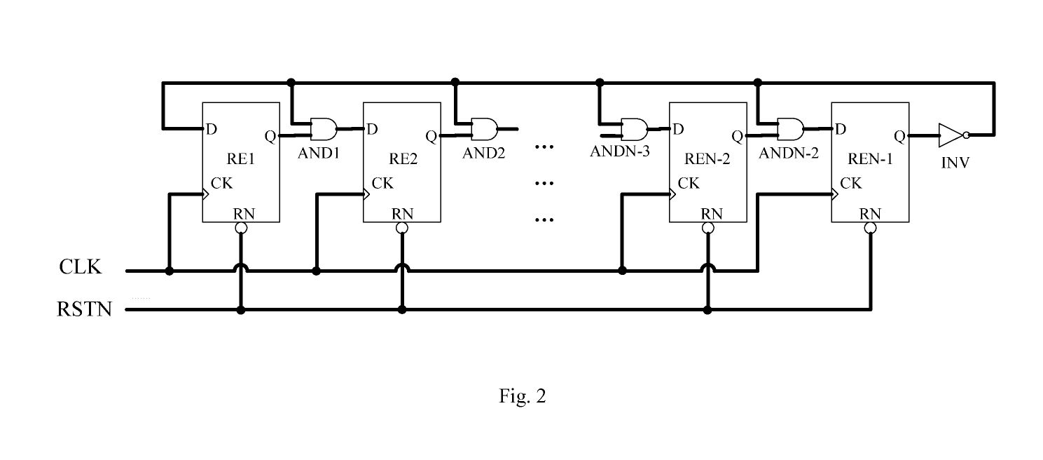

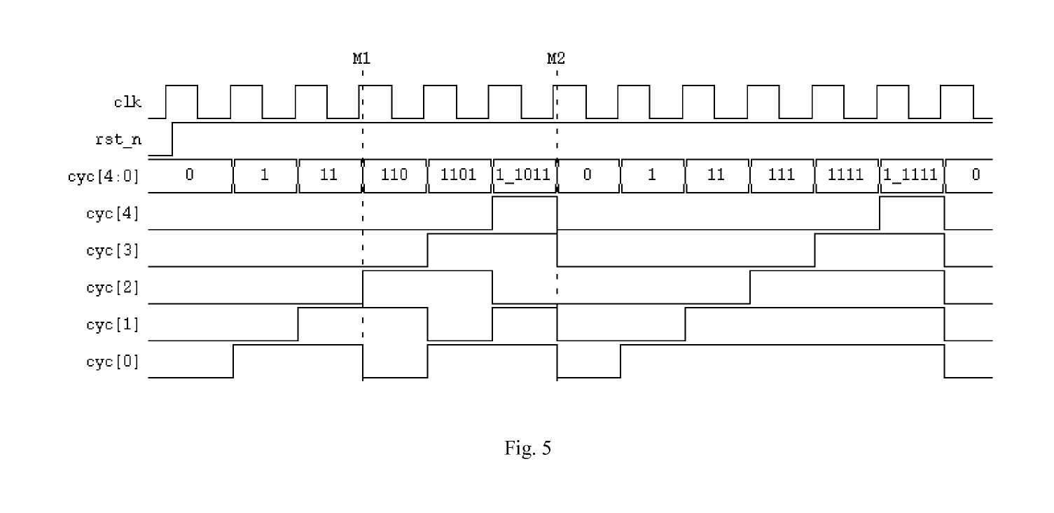

Referring to FIGS. 2-5, a first preferred embodiment of the present invention is illustrated. Referring to FIG. 2 of the drawings, the logic gate is an AND gate, the shift frequency divider according to the first preferred embodiment comprises:

an inverter INV;

N−1 registers (wherein the No. 1 register is marked as RE1, the No. 2 register is marked as RE2, . . . , and the No. N−1 register is marked as REN−1); and

N−2 AND gates (wherein the No. 1 AND gate is marked as AND1, the No. 2 AND gate is marked as AND2, . . . , and the No. N−2 AND gate is marked as ANDN−2);

wherein N, which is a positive integer larger than or equal to 2, is a frequency divider ratio of the shift frequency divider; D is an input terminal of each register, Q is an output terminal of each register, which are the same as in the following drawings; the reset terminal RN of each register is connected to a system reset signal terminal; the system reset signal terminal sends a system reset signal RSTN to the reset terminal RN of each of the registers for wholly resetting the registers at an initial state, in such a manner that all the registers are set to 1 or 0; each clock terminal CK of the registers is connected to an external high frequency clock terminal; the output terminal of the external high frequency clock terminal sends a high frequency clock CLK to the clock terminals CK of each of the registers for operating the registers; an output terminal of the No. N−1 register REN−1 is connected to an input terminal of the inverter INV, an output terminal of the inverter INV is respectively connected to an input terminal of the No. 1 register RE1 and input terminals of the AND gates for inverting an output result of the No. N−1 register REN−1 and inputting the inverted output result into the No. 1 register RE1 as well as all the AND gates; all the AND gates are respectively connected between input terminals and output terminals of the No. 1 register to the No. N−1 register, and the output terminal of the No. 1 register RE1 is connected to another input terminal of the No. 1 AND gate AND1, the output terminal N−2 of the No. N−2 register REN−2 is connected to another input terminal of the No. N−2 AND gate ANDN−2; an output terminal of the No. 1 AND gate AND1 is connected to the input terminal of the No. 2 register RE2, an output terminal of the No. N−2 AND gate ANDN−2 is connected to the input terminal of the No. N−1 register REN−1.

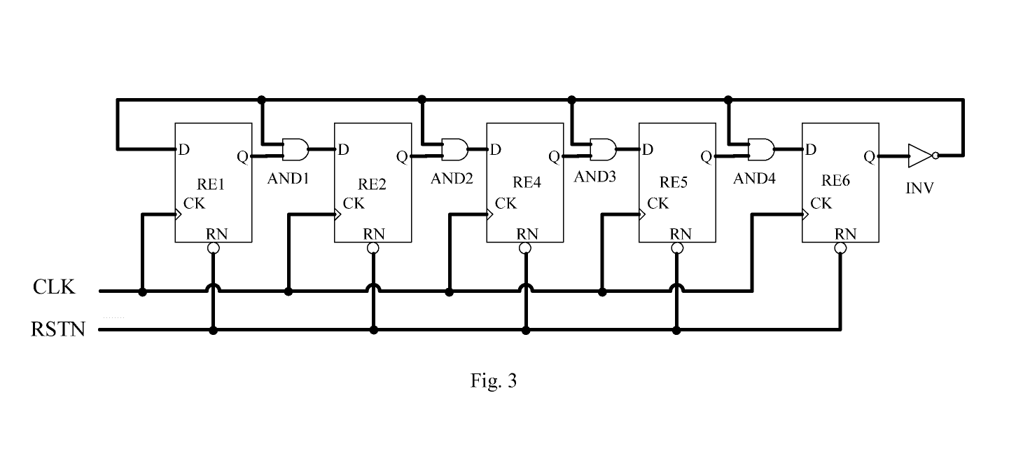

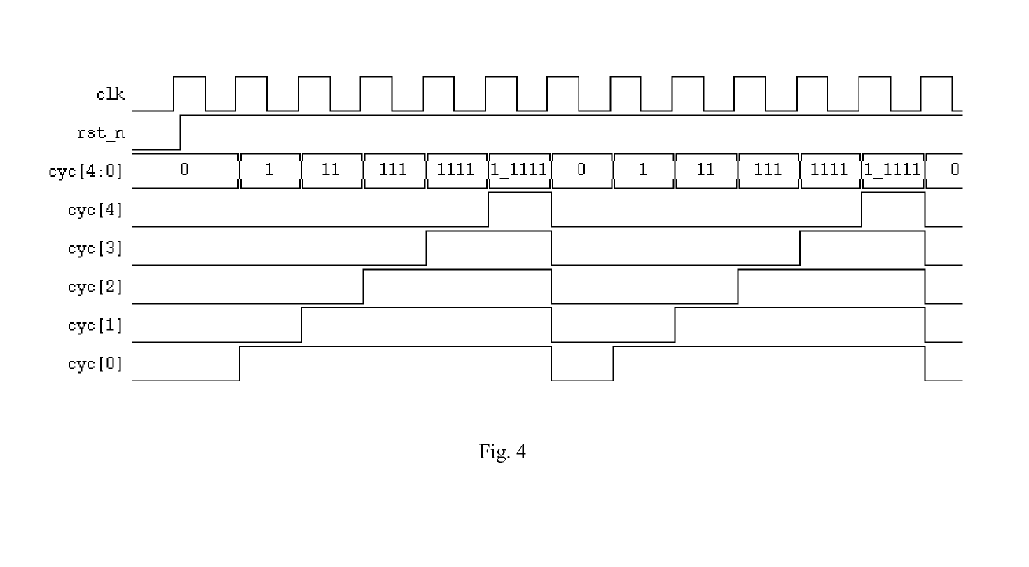

When the shift register circuit according to the first preferred embodiment works, an initial state of each of the registers is set to 0. The registers shift in turn. And each output result of each register is reversed and AND-calculated with the output result of the No. N−1 register REN−1 after being inverted before being inputted into the next register. That is to say, the output result of the No. N−1 register REN−1 is inverted and directly inputted into the input terminal of the No. 1 register, and the output result of the No. 1 register RE1 and the output result of the No. N−1 register REN−1 are reversed and are inputted into the No. 2 register RE2 after passing through the No. 1 AND gate AND1; the output result of the No. 2 register RE2 and the output result of the No. N−1 register REN−1 are reversed and are inputted into the No. 3 register RE3 after passing through the No. 2 AND gate AND2; and so forth. By this way, after N clock pulses, the No. N−1 register REN−1 is always able to reset the other N−2 registers for completely restoring the initial state. Thereafter, a cycle of the N states is provided again in such a manner that when an intermediate state of the shift frequency divider is wrong, the shift frequency divider will be recovered within a period for ensuring that the shift frequency divider works normally. Referring to FIG. 3, the shift frequency divider circuit for providing fractional-6 frequency division is illustrated. When the shift frequency divider circuit works normally, an output waveform thereof is as shown in FIG. 4. Each of the registers provides fractional-6 division clock output. However, duty ratios thereof are different, wherein the output clock duty ratio of the register in a middle (cyc[2]) is 1:1. Judging from the waveform, states of register values are respectively 00000, 00001, 00011, 00111, 01111 and 11111. The states continuously cycle so as to generate division clock. When the shift frequency divider circuit is disturbed, a state value of the registers at M1 is changed from 111 to 110 due to an abnormal condition, and the shift frequency divider enters an error state. But after a few clocks, the registers are reset at M2, and the state value thereof is recovered to a normal state 0, so as to enter a normal division state and recover from the abnormal condition. Therefore, even if disturbance happens, the shift frequency divider circuit according to the first preferred embodiment is able to be recovered with a few clocks (N−2 clocks at most), which ensures normal division.

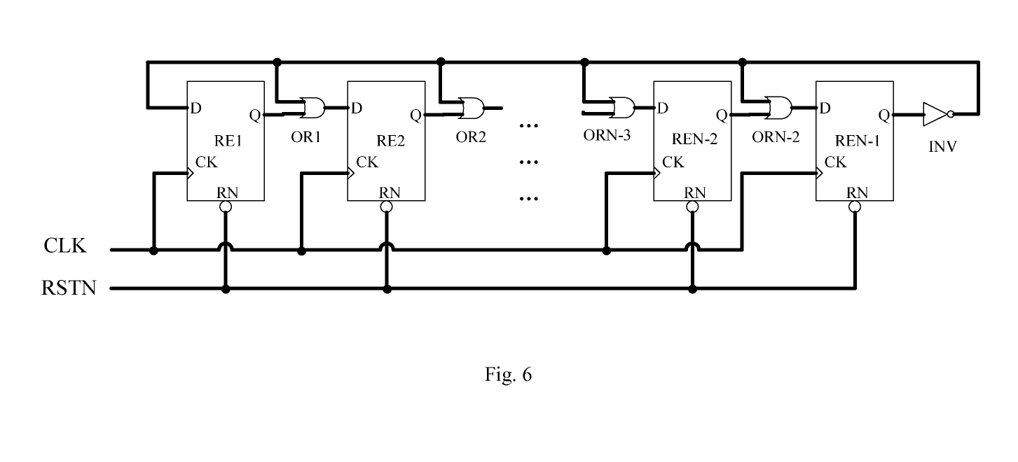

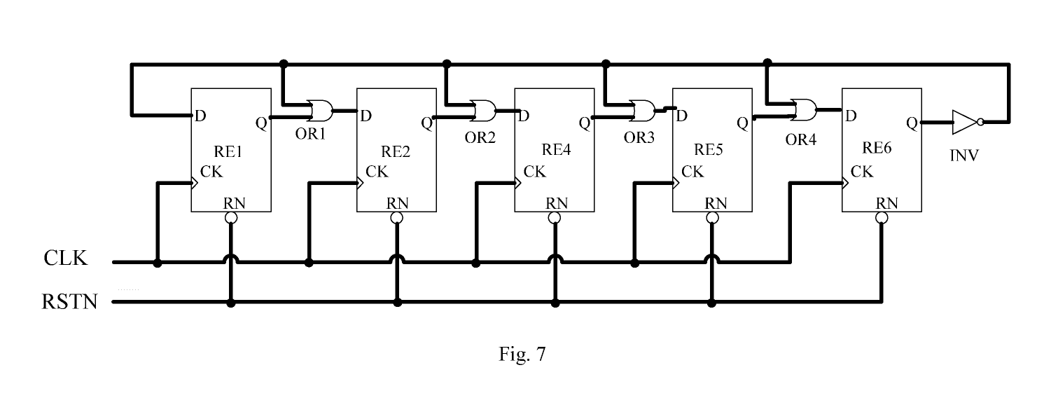

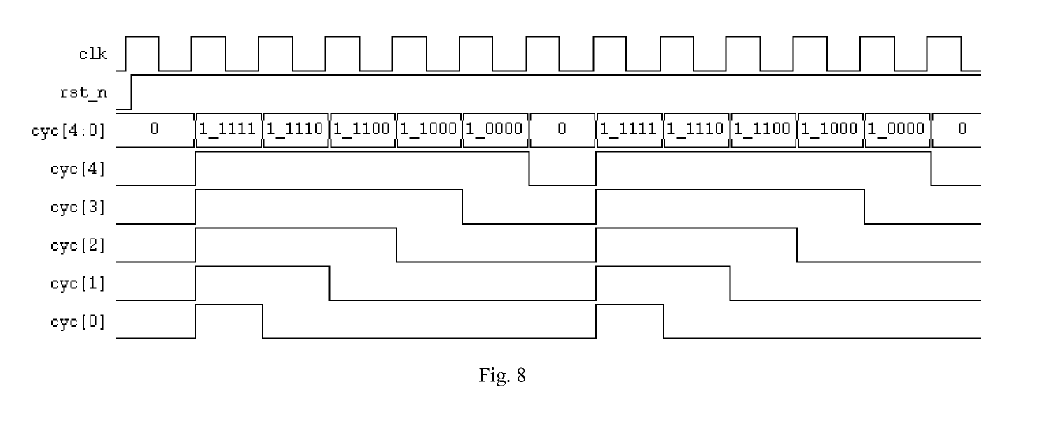

Referring to FIGS. 6-8 of the drawings, a second preferred embodiment of the present invention is provided. Referring to FIG. 6, the second preferred embodiment is similar to the first preferred embodiment except that the logic gate is an OR gate (OR1, OR2, . . . , ORN−2). And operation process is similar except for that: the second preferred embodiment, an initial state of each of the registers is set to 0 by the RSTN. And each output result of the registers is reversed and AND-calculated with the output result of the No. N−1 register REN−1 after being inverted before being inputted into the next register. At the same time, the output result of the No. N−1 register REN−1 is inverted and directly inputted into the No. 1 register. By this way, after N clock pulses, the No. N−1 register REN−1 is always able to reset the other N−2 registers for completely restoring the initial state. Thereafter, a cycle of the N states is provided again in such a manner that when an intermediate state of the shift frequency divider is wrong, the shift frequency divider will be recovered within a period for ensuring that the shift frequency divider works normally. Specifically, referring to FIG. 7, the shift frequency divider circuit for providing fractional-6 frequency division is illustrated. When the shift frequency divider circuit works normally, an output waveform thereof is as shown in FIG. 8. Judging from the waveform, states of register values are respectively 11111, 11110, 11100, 11000, 10000 and 00000. The states continuously cycle so as to generate division clock. When the shift frequency divider circuit is disturbed, a state value of the registers at M1 is changed from 11100 to 10111 due to an abnormal condition, and the shift frequency divider enters an error state. But after a few clocks, the registers are reset at M2, and the state value thereof is recovered to a normal state 1, so as to enter a normal division state and recover from the abnormal condition.

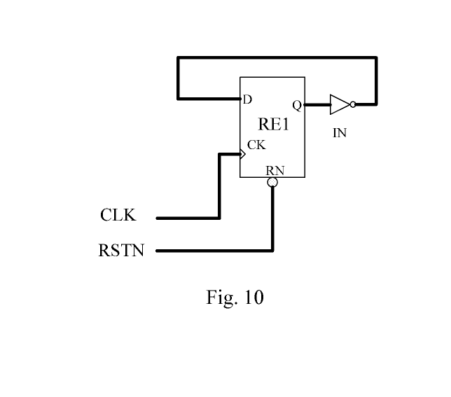

Referring to FIG. 10 of the drawings, a third preferred embodiment of the present invention is illustrated, wherein the shift frequency divider circuit provides fractional-2 division of the high frequency clock CLK, and the third preferred embodiment is similar to the other preferred embodiments except for no logic gate involved. Specifically, the shift frequency divider circuit comprises:

an inverter INV; and

a register RE1.

Connection relationship thereof is as shown in the FIG. 10 and will not be further illustrated. Because only one register is utilized, the register has only two states: 0 and 1. As a result, even if the intermediate state of the shift frequency divider circuit is wrong, a result is still one of the two states. Therefore, the shift frequency divider circuit according to present invention is able to provide the normal fractional-2 division of the high frequency clock CLK and will not be affected by the abnormal intermediate state.

One skilled in the art will understand that the embodiment of the present invention as shown in the drawings and described above is exemplary only and not intended to be limiting.

It will thus be seen that the objects of the present invention have been fully and effectively accomplished. Its embodiments have been shown and described for the purposes of illustrating the functional and structural principles of the present invention and is subject to change without departure from such principles. Therefore, this invention includes all modifications encompassed within the spirit and scope of the following claims.

What is claimed is:

1. A shift frequency divider circuit, which is a fractional-N shift frequency divider circuit, wherein said N is a positive integer larger than or equal to 2; said shift frequency divider circuit comprises:
an inverter;
N−1 registers; and
N−2 logic gates;
wherein a reset terminal of each register is connected to a system reset signal terminal; a clock terminal of each register is connected to an external high frequency clock terminal; an output terminal of said No. N−1 register is connected to an input terminal of said inverter, an output terminal of said inverter is respectively connected to an input terminal of said No. 1 register and input terminals of all said logic gates; all said logic gates are respectively connected between output terminals and input terminals of said No. 1 register to said No. N−1 register, and said output terminal of said No. 1 register is connected to another input terminal of said No. 1 logic gate, an output terminal of said No. 1 logic gate is connected to said input terminal of said No. 2 register, said output terminal of said No. N−2 register is connected to another input terminal of said No. N−1 logic gate; and, an output terminal of said No. N−2 logic gate is connected to said input terminal of said No. N−1 register.

2. The shift frequency divider circuit, as recited in claim 1, wherein the N equals to 2; said shift frequency divider circuit comprises:
an inverter; and
a register;
wherein an output terminal of said register is connected to an input terminal of said inverter; an output terminal of said inverter is connected to an input terminal of said register.

3. The shift frequency divider circuit, as recited in claim 2, wherein said logic gate is an AND gate.

4. The shift frequency divider circuit, as recited in claim 2, wherein said logic gate is an OR gate.
